(19) United States
(12) Patent Application Publication
(10) Pub. No.: US 2025/0157831 A1
(43) Pub. Date: May 15, 2025

(54) DEVICE FOR CONTROLLING GAS FLOW OF EQUIPMENT FRONT END MODULE AND SEMICONDUCTOR PROCESS APPARATUS COMPRISING THE SAME

(71) Applicant: Justem Co., Ltd., Yongin-si (KR)

(72) Inventors: Young Jin LIM, Yongin-si (KR); In Keun WOO, Yongin-si (KR); Hui Jin, Hwaseong-si (KR)

(21) Appl. No.: 18/938,607

(22) Filed: Nov. 6, 2024

(30) Foreign Application Priority Data
Nov. 13, 2023 (KR) 10-2023-0156619
Jan. 29, 2024 (KR) 10-2024-0013031

(51) Int. Cl. H01L 21/67

(52) U.S. Cl. CPC H01L 21/67017

(57) ABSTRACT

The present invention relates to a device for controlling a gas flow of an equipment front end module (EFEM), which is installed at one side or each of both sides of an internal space of the EFEM to form a gas layer at an entrance, through which a wafer is loaded and unloaded, and a semiconductor process apparatus including the same, and includes a body part installed at an upper portion of a front surface of the entrance, a blower part configured to blow the gas so that the gas is supplied into the body part, a dispersion part installed at a lower portion of the body part. Thus, the present invention may provide an effect of blocking an introduction of external air by installing the body part, the blower part, and the dispersion part at one side or both sides in the internal space of the EFEM to form the gas layer at the entrance of the wafer, thereby forming a blocking gas layer at the entrance so as to reduce humidity of a wafer container.

### CROSS-REFERENCE TO RELATED APPLICATIONS

This U.S. non-provisional patent application claims priorities under 35 U.S.C. § 119 of Korean Patent Application Nos. 10-2023-0156619, filed on Nov. 13, 2023, and 10-2024-0013031, filed on Jan. 29, 2024, the entire contents of which are hereby incorporated by reference.

### FIELD OF THE INVENTION

The present invention disclosed herein relates to a device for controlling a gas flow of an equipment front end module (EFEM) and a semiconductor process apparatus comprising the same, and more particularly, to a device for controlling a gas flow of an EFEM, which is installed in a transfer chamber of the EFEM to supply and intake air so as to stabilize the gas flow of the transfer chamber, and a semiconductor process apparatus including the same.

### BACKGROUND ART

In a semiconductor manufacturing process, a wafer and a semiconductor element formed on the wafer are high-precision items, and care should be taken to prevent damage from external contaminants and an impact during storage and transfer. Particularly, during the storage and transfer of the wafer, care should be taken to prevent surfaces of the wafer from being contaminated with impurities such as dust, moisture, and various organic substances.

In the related art, wafer processing has been performed in a clean room to improve semiconductor manufacturing yield and quality. However, as integration and miniaturization of components and enlargement of the wafer are progressed, it has become difficult to manage the clean room, which is a relatively large space, both in terms of costs and technologies.

Recently, instead of improving cleanliness of the entire clean room, a method for cleaning a local environment (mini-environment) is applied to concentrately improve the cleanliness of a local space around the wafer.

The semiconductor manufacturing process involves various unit processes such as etching, deposition, and etching, which are sequentially repeated. There is a limitation in which foreign substances or contaminants remain on the wafer during each process to cause defects or deterioration in semiconductor process yield.

Thus, in the semiconductor processes, the wafer is transferred to several process chambers or semiconductor processing spaces. Here, various units are provided to minimize the foreign substances or the contaminants from being attached to the wafer while the wafer is transferred from one processing space to another processing space.

A semiconductor process apparatus including an equipment front end module (EFEM) is configured to include a load port module (LPM) 110, a wafer container 120 (e.g., front opening unified pod (FOUP)), a fan filter unit (FFU) 130, and a wafer transfer chamber 140, as illustrated in FIGS. 1 to 4.

To store a wafer under a highly clean environment, the wafer container 120 that is called a front-opening unified pod (FOUP) is used, the wafer transfer chamber 140 is formed in a path along which the wafer moves from the wafer container 120 to a semiconductor processing space, and the wafer transfer chamber 140 is maintained as a clean space by a fan filter unit 130.

The wafer in the wafer container 120 is configured to be unloaded into the wafer transfer chamber 140 through the load port module 110 or be loaded from the wafer transfer chamber into the wafer container 120 by a wafer transfer robot 150 such as an arm robot.

A door 121 of the load port module 110 and a door installed on a front surface of the wafer container 120 are opened at the same time in a state of being in close contact with each other, and the wafer is unloaded or loaded through an opened area.

In general, fumes generated after the process remain on a surface of the wafer that undergoes the semiconductor processing process, and this causes a chemical reaction to deteriorate productivity of the semiconductor wafer.

Furthermore, when the door 121 of the wafer container 120 is opened for loading or unloading the wafer, a purge gas concentration inside the wafer container 120 is controlled to be maintained at a certain level, and external air introduced into the wafer container is filtered.

However, due to the external air introduced into the wafer container 120, air that is not partially filtered exists inside the wafer container 120. Thus, although an atmospheric environment of the wafer transfer chamber 140 is clean air with controlled particulates, the clean air contains oxygen, moisture, etc., and if the air is introduced into the inside of the wafer container 120 to increase in internal humidity, there is a possibility that the surface of the wafer is oxidized by moisture or oxygen contained in the external air.

Thus, in the related art, a double door opening/closing unit provided to block the external air by opening/closing covers of the load port module 110 and the wafer container 120 is provided as a unit for effectively blocking the external air from being introduced into the wafer container 120 from the wafer transfer chamber 140, but there is a limitation in that a configuration of the load port became considerably complicated by providing a door 121 that is slid vertically.

In addition, as a door member moves vertically to block the external air, a time required to load or unload the wafer increases significantly to cause a change in internal humidity of the wafer container, thereby deteriorating the semiconductor manufacturing yield.

Particularly, there is also a limitation that, when the external air is introduced into the inside of the wafer container 120 through an entrance, through which the wafer is loaded into and unloaded from the wafer container 120, to increase in internal humidity at the entrance, the surface of the wafer is damaged by the moisture or oxygen contained in the external air to deteriorate the yield.

Thus, to achieve the high integration and the yield improvement of the semiconductor, the internal cleanliness management of the EFEM is becoming important, and in particular, there is a limitation that fumes are generated inside the EFEM of an etching process equipment after the process is performed, and as illustrated in FIG. 2, the fumes are spread throughout the entire inside of the EFEM, and the fumes are also generated in the wafers loaded again into the FOUP after the process is completed.

To remove the fumes, a gas flow is generated at an upper end of the EFEM due to the FFU and the is discharged to a lower portion of the EFEM. However, in this case, there is a limitation that the fumes are not naturally discharged, but rather, when discharged by a pressure of the FFU, an undesirable side discharge occurs due to the EFEM, as illustrated in FIG. 2, because of an unsealed structure.

In addition, since the natural exhaust to the outside of the EFEM is harmful to the human body, various methods have been proposed to solve this limitation. The exhaust device according to the related art has been proposed in which a forced exhaust outlet is provided near the transfer robot.

The exhaust device that discharges to an exhaust line 170 provided with a horizontal exhaust duct 171 near the transfer robot according to the related art has a structure that controls an exhaust amount at a corresponding position in a horizontal structure that fills the inside of the EFEM at a position that is slightly lower than the FOUP compared to an inlet of a process equipment. Thus, a suddenly narrowed exhaust structure may be provided in the transfer path of the process wafer to generate an eddy current inside the EFEM, and thus, there is a limitation that it is difficult to effectively discharge the fumes.

In particular, the eddy current is concentrated to an outer peripheral portion of the EFEM, and there is also a limitation that the eddy current of the fumes is generated in a region in which the most fumes are generated, and the occurrence of the eddy current is more serious because a speed of the gas flow outside the EFEM is slower than that at the center.

In addition, as illustrated in FIGS. 3 and 4, a separate gas is supplied to an upper portion of the wafer container 120 to control the humidity and the gas flow of the wafer container 120, but there is a limitation in that the lifespan of internal components is short because the fumes or foreign gases that has a fatal effect on the particles and wafer inside the FOUP are not be captured.

Particularly, after a multi-process of the fumes (containing Cl, F, etc.) in the semiconductor processing equipment, the fumes emitted from the wafer is spread by the gas flow of the EFEM to cause overall corrosion and concentrating on an area of the door, and thus, measures for preventing this corrosion are needed.

### PRIOR ART DOCUMENT

### Patent Document

Korean Patent Registration No. 10-1758214 (Jul. 14, 2017)
Korean Patent Registration No. 10-2100775 (Apr. 14, 2020)
Korean Patent Registration No. 10-2124372 (Jun. 18, 2020)

### SUMMARY OF THE INVENTION

To solve the above-mentioned limitations, the present invention provides a device for controlling a gas flow of an EFEM, which is capable of forming a blocking gas layer at an entrance to block an introduction of external air, thereby reducing humidity at an entrance space of a wafer, and a semiconductor process apparatus including the same.

The present invention also provide a device for controlling a gas flow of an EFEM, which is capable of forming multiple gas layers by a downward flow in a blower part and an upward flow or inward flow in a nozzle part to reduce an interference due to a flow of air in a wafer transfer chamber and control a flow of a gas that forms an external air blocking gas layer, and a semiconductor process apparatus including the same.

The present invention also provide a device for controlling a gas flow of an EFEM, which is capable of solving limitations of increasing in time required for unloading and loading a wafer due to a conventional complex load port and improving manufacturing yield of a semiconductor while effectively blocking external air, and a semiconductor process apparatus including the same.

The present invention also provide a device for controlling a gas flow of an EFEM, which is capable of uniformly maintaining a gas layer for each areas while improving maintenance performance of a gas layer by finely controlling the gas flow amount for each area at an upper portion of an entrance, and a semiconductor process apparatus including the same.

The present invention also provide a device for evenly distributing a gas in a straight line to an upper portion of an entrance to uniformly maintain a gas layer, and a semiconductor process apparatus including the same.

The present invention also provide a device for controlling a gas flow of an EFEM, which is capable of filtering a gas supplied by a blower part to remove foreign substances or impurities such as fine dusts contained in the gas through filtration, thereby preventing contamination of the gas distributed and supplied by a blower part and a dispersion part so as to improve yield of a wafer container, and a semiconductor process apparatus including the same.

The present invention also provide a device for controlling a gas flow of an EFEM, which is capable of suctioning and discharging a large amount of fumes generated after a semiconductor process to decrease in humidity inside a FOUP, thereby improving semiconductor production yield, and a semiconductor process apparatus including the same.

The present invention also provide a device for controlling a gas flow of an EFEM, which is installed in a door of a FOUP of an EFEM of a semiconductor equipment to suction and discharge a corrosive gas and external air inside the FOUP, and a semiconductor process apparatus including the same.

The present invention also provide a device for controlling a gas flow of an EFEM, which is capable of partitioning a plurality of intake ports and intake zones in an upper portion of a door and dividing a plurality of suction zones into a plurality of parts to control an intake amount for each positions, thereby improving suction uniformity for suction efficiency of a corrosive gas and external air, and a semiconductor process apparatus including the same.

The present invention also provide a device for controlling a gas flow of an EFEM, which is capable of sequentially disposing an intake part, a tube part, a control part, a manifold part, and a discharge part downward to improve intake performance and discharge performance and also improve stabilization of the gas flow, and a semiconductor process apparatus including the same.

According to an embodiment of the present invention, a device for controlling a gas flow of an equipment front end module (EFEM), which is installed at one side or each of both sides of an internal space of the EFEM, wherein the device is installed at an entrance, through which a wafer is loaded and unloaded, to supply a gas to stabilize the gas flow, includes: a body part (210) installed at an upper portion of a front surface of the entrance; a blower part (220) configured to blow the gas so that the gas is supplied into the body part (210); and a dispersion part (230) installed at a lower portion of the body part (210), wherein the gas supplied into the body part (210) is uniformly dispersed downward in a straight line to discharge the gas, thereby forming a gas layer.

The device may further include a nozzle part (240) installed at a lower portion of the front surface of the entrance to supply the gas upward or inward. The nozzle part (240) may be provided as a gas nozzle installed at each of both ends of the lower portion of the entrance to inject the gas into a wafer container.

The device may further include a gas injection part (250) installed at an upper portion or a side portion of the body part (210) to inject a nitrogen gas or a low-humidity gas to the upper portion of the entrance.

The body part (210) may include: a cylindrical main body which is provided to be penetrated in a vertical direction and in which partition walls are installed to partition an internal space into a plurality of spaces, respectively; an inclined piece installed to be inclined at an upper portion of the main body; and a cover piece which is installed to be coupled to an upper portion of the inclined piece and in which a plurality of through-holes are punched.

The blower part (220) may be provided as a blower unit installed inside the body part (210) or installed to be connected outside the body part (210) by interposing a connection tube therein.

The blower unit may include: one or more first blower fans installed at one side portion of the body part (210); one or more second blower fans installed at a central portion of the body part (210); and one or more third blower fans installed at the other side potion of the body part (210).

The blower part (220) may be provided with partition walls configured to partition a blowing space of the blower unit into a plurality of spaces.

The dispersion part (230) may be provided as a distribution tube in which a plurality of through-holes having a cross-section in a honeycomb shape so that the gas is distributed and injected to the upper portion of the entrance in a straight line.

The device may further include a filter part (260) installed between the blower part (220) and the dispersion part (230) to filter the gas supplied by the blower part (220).

The device may further include a control part (270) connected to the blower part (220) to control a blowing amount of the blower part (220).

According to another embodiment of the present invention, a semiconductor process apparatus is provided with the device for controlling the gas flow of the EFEM of the present invention.

According to further another embodiment of the present invention, a device for controlling a gas flow of an equipment front end module (EFEM), which is installed at one side or each of both sides of an internal space of the EFEM, wherein the device is installed at an entrance, through which a wafer is loaded and unloaded, to supply a gas to stabilize the gas flow, includes: an intake part (10) in which an intake space is partitioned into a plurality of intake zones at a wafer entrance door; a tube part (30) connected to the intake part (10) to communicate with each of the intake zones; a control part (20) installed in a communication path of the of the tube part (30) to individually control an intake amount of each of the intake zones; a manifold part (40) connected downstream of the tube part (30) to combine an intake gas of each of the intake zones; and a discharge part (50) installed at one side of the manifold part (40) to provide intake force to the manifold part (40), thereby discharging the intake gas introduced into the manifold part (40).

The intake part (10) may include: an intake zone that is partitioned into a plurality of zones so that the gas is suctioned for each zone in the intake space; and an intake port provided downstream of each of the intake zones.

The manifold part (40) may include: a first manifold configured to combine the intake gas suctioned from each of the intake zones of the intake part (10); a first exhaust port installed at one side of the first manifold to discharge a residual gas; a first inlet installed at an upper portion of the first manifold and connected to each intake zone of the intake part (10) to introduce the intake gas; and a first outlet installed at the other side of the first manifold to discharge the intake gas.

The manifold part (40) may include: a second manifold configured to combine the intake gas suctioned from each of the intake zones of the intake part (10); a second inlet installed at a circumference of the second manifold and connected to each intake zone of the intake part (10) to introduce the intake gas; and a second outlet installed at a lower portion of the second manifold to discharge the intake gas.

The discharge part (50) may include: a suction unit installed downstream of the manifold part (40) to provide intake force; an input port installed upstream of the suction unit to input the intake gas; and a discharge port installed downstream of the suction unit to discharge the intake gas.

According to another embodiment of the present invention, a semiconductor process apparatus is provided with the device for controlling the gas flow of the EFEM of the present invention.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a configuration of an EFEM according to a related art;

FIG. 2 is a view illustrating a state of a gas flow of the EFEM according to the related art;

FIG. 3 is a view illustrating a configuration of a semiconductor process apparatus provided with a device for controlling a gas flow of the EFEM according to the related art;

FIG. 4 is a view illustrating a state of the gas flow in the semiconductor process apparatus provided with the device for controlling the gas flow of the EFEM according to the related art;

FIG. 5 is a view illustrating a configuration of a semiconductor process apparatus provided with a device for controlling a gas flow of an EFEM according to an embodiment of the present invention;

FIG. 6 is a bottom perspective view illustrating the device for controlling the gas flow of the EFEM according to an embodiment of the present invention;

FIG. 7 is a top perspective view illustrating the device for controlling the gas flow of the EFEM according to an embodiment of the present invention;

FIG. 8 is an exploded perspective view illustrating the device for controlling the gas flow of the EFEM according to an embodiment of the present invention;

FIG. 9 is a cross-sectional view illustrating the device for controlling the gas flow of the EFEM according to an embodiment of the present invention;

FIG. 10 is a bottom perspective view illustrating the device for controlling the gas flow of the EFEM according to an embodiment of the present invention;

FIGS. 11 and 12 are views illustrating an example of a blower part of the device for controlling the gas flow of the EFEM according to an embodiment of the present invention;

FIG. 13 is a view illustrating another example of a blower part of the device for controlling the gas flow of the EFEM according to an embodiment of the present invention;

FIGS. 14 and 15 are views illustrating a nozzle part of the device for controlling the gas flow of the EFEM according to an embodiment of the present invention;

FIGS. 16 and 17 are views illustrating a gas injection part of the device for controlling the gas flow of the EFEM according to an embodiment of the present invention;

FIG. 18 is a view illustrating an example of a semiconductor process apparatus provided with the device for controlling the gas flow of the EFEM according to an embodiment of the present invention;

FIG. 19 is a view illustrating a state in which the device for controlling the gas flow of the EFEM is installed according to an embodiment of the present invention;

FIG. 20 is a view illustrating a cover part of the device for controlling the gas flow of the EFEM according to an embodiment of the present invention;

FIG. 21 is a view illustrating another example of the semiconductor process apparatus provided with the device for controlling the gas flow of the EFEM according to an embodiment of the present invention;

FIG. 22 is a view illustrating an example of the device for controlling the gas flow of the EFEM according to an embodiment of the present invention;

FIG. 23 is a view illustrating another example of the device for controlling the gas flow of the EFEM according to an embodiment of the present invention; and

FIG. 24 is a view illustrating further another example of the device for controlling the gas flow of the EFEM according to an embodiment of the present invention.

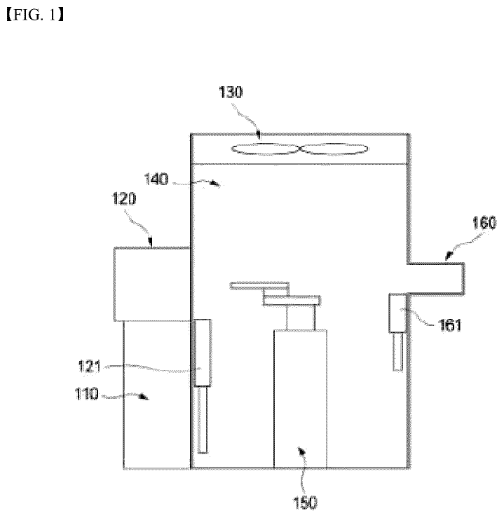

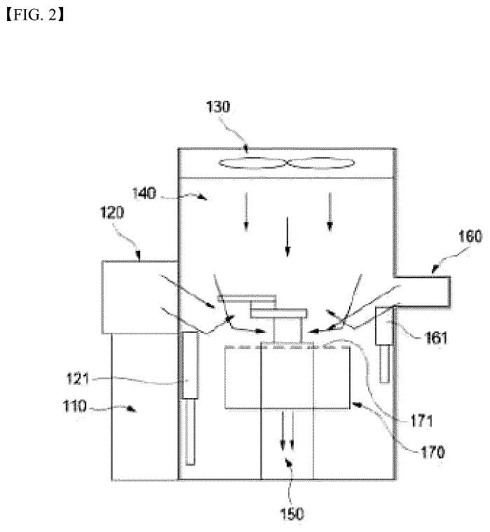

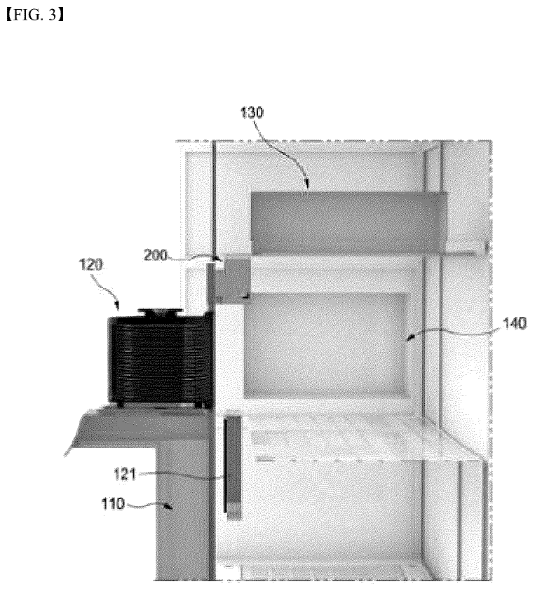

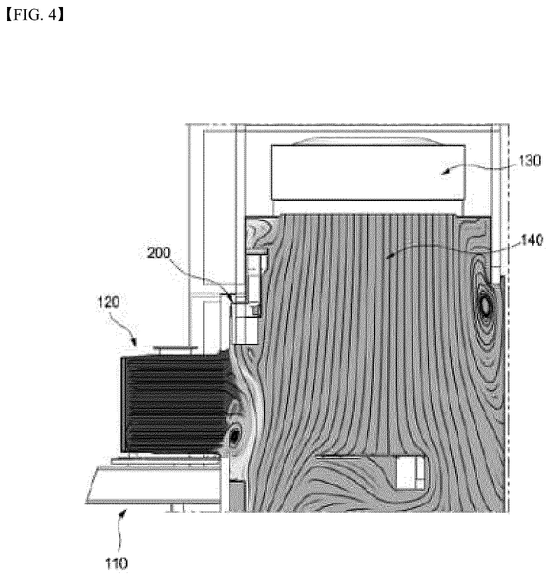

### DETAILED DESCRIPTION OF THE PREFERRED EMBODIMENTS

Hereinafter, a device for controlling a gas flow of an EFEM according to a preferred embodiment of the present invention will be described in more detail with reference to the attached drawings.

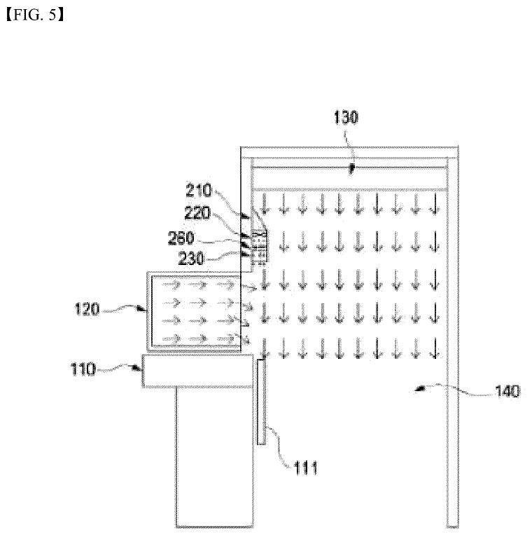

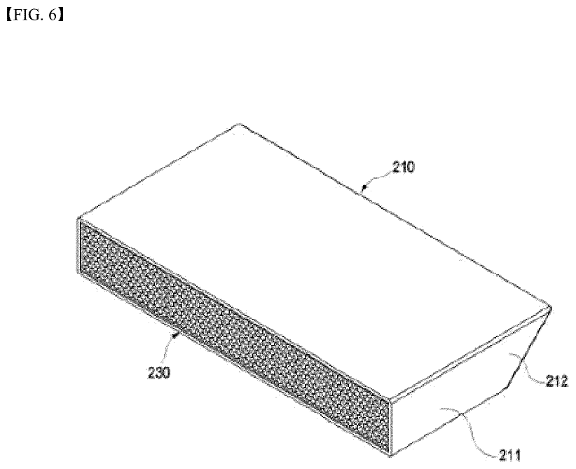

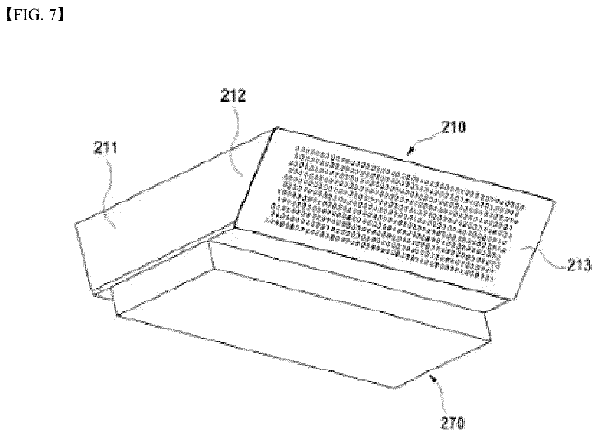

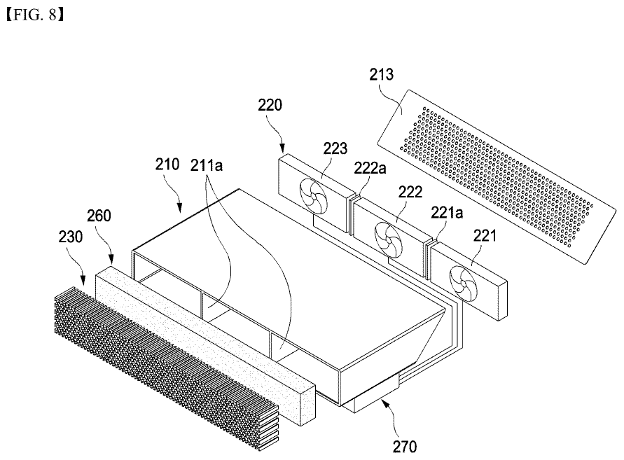

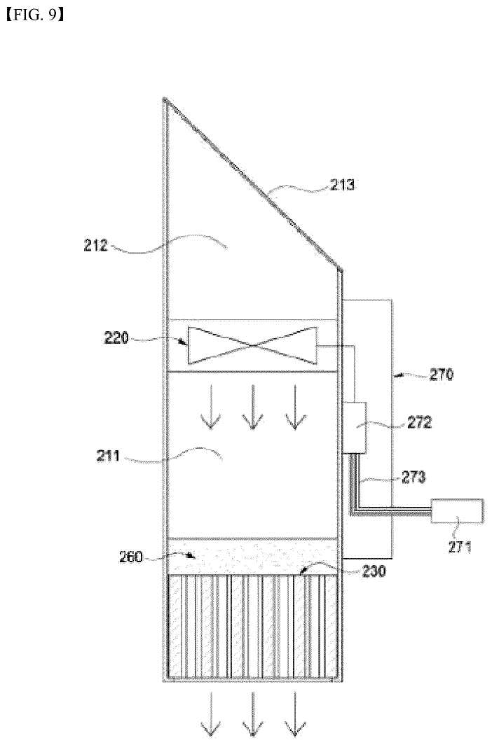

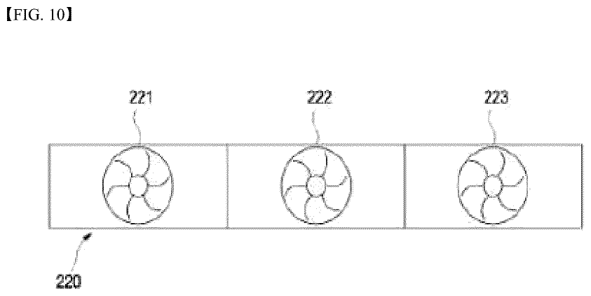

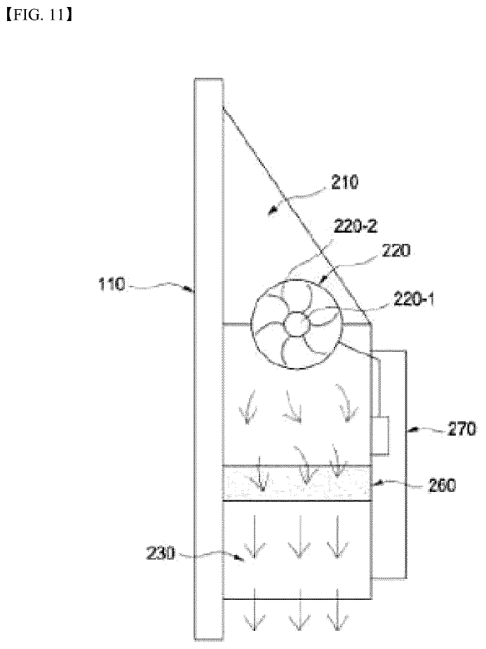

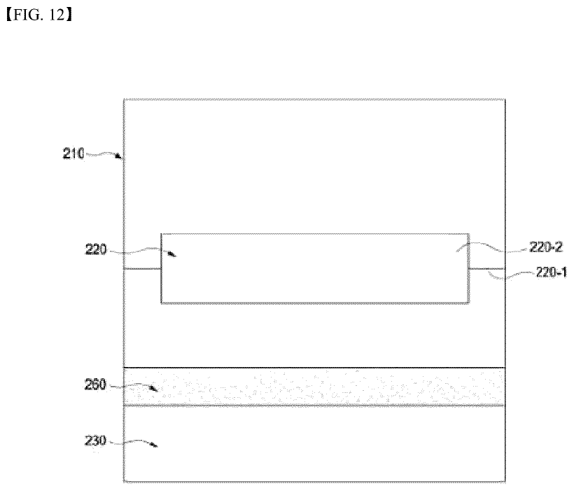

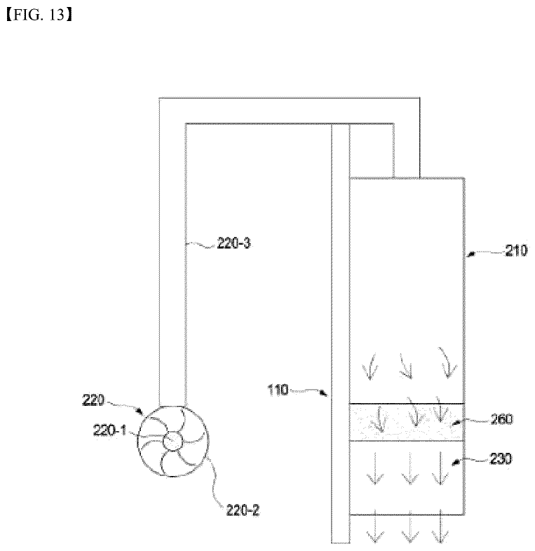

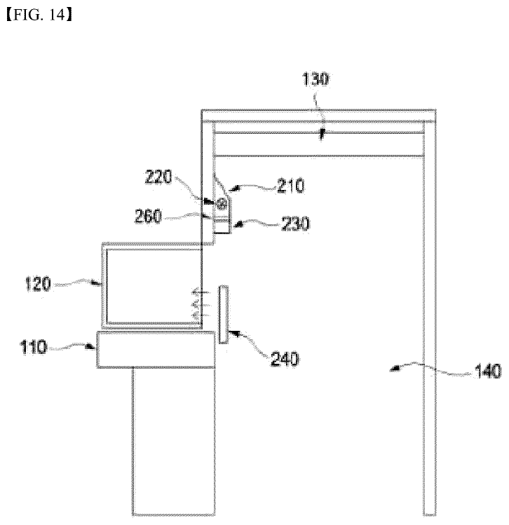

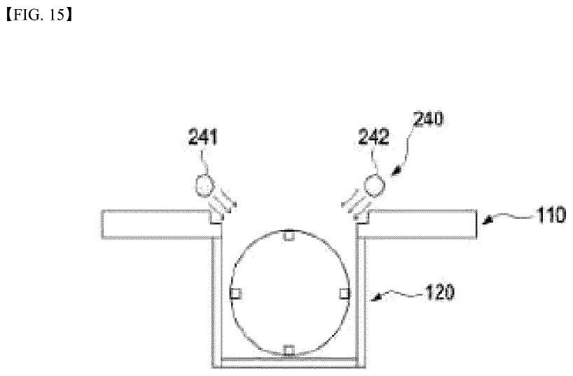

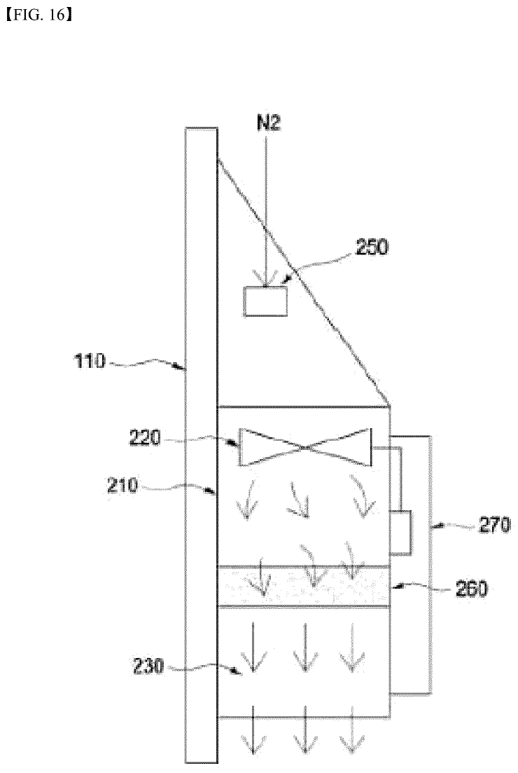

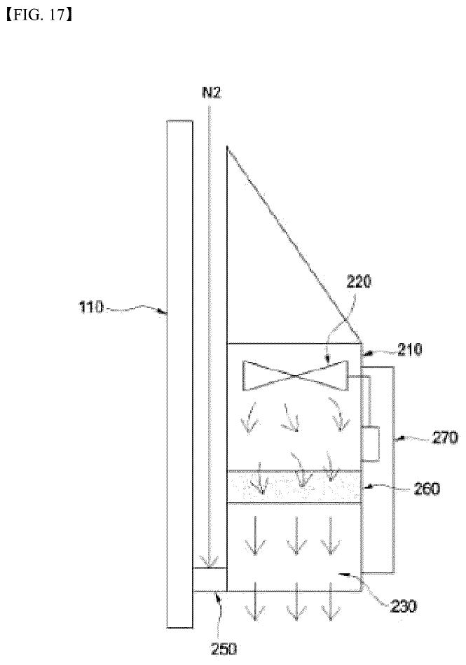

FIG. 5 is a view illustrating a configuration of a semiconductor process apparatus provided with a device for controlling a gas flow of an EFEM according to an embodiment of the present invention, FIG. 6 is a bottom perspective view illustrating the device for controlling the gas flow of the EFEM according to an embodiment of the present invention, FIG. 7 is a top perspective view illustrating the device for controlling the gas flow of the EFEM according to an embodiment of the present invention, FIG. 8 is an exploded perspective view illustrating the device for controlling the gas flow of the EFEM according to an embodiment of the present invention, FIG. 9 is a cross-sectional view illustrating the device for controlling the gas flow of the EFEM according to an embodiment of the present invention, FIG. 10 is a bottom perspective view illustrating the device for controlling the gas flow of the EFEM according to an embodiment of the present invention, FIGS. 11 and 12 are views illustrating an example of a blower part of the device for controlling the gas flow of the EFEM according to an embodiment of the present invention, FIG. 13 is a view illustrating another example of a blower part of the device for controlling the gas flow of the EFEM according to an embodiment of the present invention, FIGS. 14 and 15 are views illustrating a nozzle part of the device for controlling the gas flow of the EFEM according to an embodiment of the present invention, and FIGS. 16 and 17 are views illustrating a gas injection part of the device for controlling the gas flow of the EFEM according to an embodiment of the present invention.

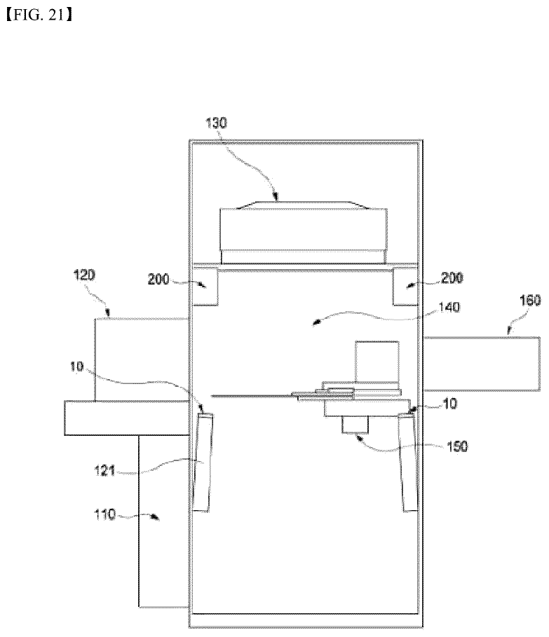

A semiconductor process apparatus of the present invention may be a semiconductor process apparatus provided with the device for controlling the gas flow of the EFEM according to this embodiment, and as illustrated in FIG. 5 and FIG. 21, may include a load port module (LPM) 110, a wafer container 120 (e.g., front opening unified pod (FOUP)), a fan filter unit (FFU) 130, and a wafer transfer chamber 140 and may be provided as an equipment front end module (EFEM) on which a device for controlling a gas flow of the EFEM is mounted.

The load port module (LPM) 110 may be a device that opens or closes a door 111 of the wafer container 120 (e.g., front opening universal pod (FOUP)) containing wafers for semiconductor manufacturing to transfer the wafers.

This load port module (LPM) 110 may be configured to inject a nitrogen gas into the wafer container 120 (e.g., front opening unified pod (FOUP)) when the wafer container 120 is mounted on a stage unit and discharge contaminants inside the wafer container 120 to the outside of the wafer container 120, thereby preventing the wafers stored and transferred in the wafer container 120 from being damaged by the contaminants.

The device for controlling the gas flow of the EFEM according to this embodiment may be installed on a front surface of the wafer container 120 between the wafer container 120 and the wafer transfer chamber 140 to form an external air blocking gas layer or a gas curtain at an entrance through which the wafer is loaded and unloaded so that internal humidity of the wafer container 120 is maintained at a set value, thereby stabilizing the gas flow.

The wafer container 120 may have a loading space, in which the plurality of wafers are loaded, therein, and the door may be opened to load or unload the wafers. The wafer container 120 may be provided as the front-opening unified pods (FOUP).

The wafer transfer chamber 140 may provide a space defined between the wafer container 120, in which the plurality of wafers are loaded, and a processing space (not shown), in which the wafers are processed by a semiconductor process. The wafer transfer chamber 140 may be maintained as a clean space to minimize foreign substances or contaminants from being attached to the wafers while the waters are transferred from one processing space to another processing space by a transfer unit such as a transfer robot.

The fan filter unit 130 may be installed at an upper portion of the wafer transfer chamber 140 to remove molecular contaminants such as fumes and fine particles such as dusts, thereby maintaining air inside the wafer transfer chamber 140 in a clean state. Typically, an air flow within the wafer transfer chamber 140 may be formed downward from the upper portion, at which the fan filter unit 130 is installed.

As illustrated in FIGS. 5 to 8 and FIG. 21, the device 200 for controlling the gas flow of the EFEM according to this embodiment may be the device for controlling the gas flow of the EFEM, which includes a body part 210, a blower part 220, and a dispersion part 230 and is installed at one side or both sides of an internal space of the EFEM and also installed at the entrance, through which the wafers are loaded and unloaded, to supply a gas so that the gas flow is stabilized, thereby forming a gas curtain or a gas layer such as the gas curtain at the entrance, through which the wafers are loaded and unloaded, so as to reduce humidity of the internal space.

The body part 210 may be a body member which is installed at one side or each of both sides of the internal space of the EFEM and also is installed at the entrance, through which the wafer are loaded and unloaded, and includes a main body 211, an inclined piece 212, and a cover piece 213.

The main body 211 may be a cylindrical body member having a through-hole defined therein to be penetrated vertically, and installed at the upper portion of the entrance and may be provided as a rectangular box member disposed in a straight line along a longitudinal direction between one end and the other end of the upper portion of the entrance.

A plurality of partition walls 211a that partition the internal space into a plurality of spaces to induce a flow of a purge gas or pure air may be installed in the main body 211 so that the purge gas or the pure gas is introduced from an upper side and then discharged to a lower side by the fan filter unit 130.

The inclined piece 212 may be an inclined member installed to be inclined at an upper portion of the main body 211 and be provided with a communication member that is installed to communicate with the upper portion of the main body 211 and is cut to be inclined backward and downward from a front side of the entrance so that the purge gas or pure air introduced from the upper side is easily introduced.

The cover piece 213 may be a cover member installed to be coupled to the inclined portion at an upper portion of the inclined piece 212 and may be provided as a cover member having a plurality of through-holes punched therein so that the purge gas or the pure gas introduced from the upper portion of the entrance is dispersed and introduced to the upper portion of the entrance.

The blower part 220 may be a supply unit for blowing the gas such as the purge gas or the pure air into the body part 210 and may be provided as a blower unit installed inside the body part 210 or installed to be connected with a communication tube therein, and also, a plurality of partition walls 221a and 222a, which partition a blowing space into a plurality of spaces to induce the flow of the purge gas or the pure air, may be installed therein.

As illustrated in FIGS. 8 to 10, the blower unit may include a first blower fan 221 installed in plurality at one side of the body part 210, a second blower fan 222 installed in plurality at a central portion of the body part 210, and a third blower fan 223 installed in plurality at the other side of the body part 210 and may be connected to each driving motor and control piece so that a blowing amount and a gas speed are controlled individually or for each installed portion.

In addition, as illustrated in FIGS. 11 to 13, the blower unit may be provided as one tower-type blower fan 220-2 that rotates with respect to a horizontal shaft 220-1 installed horizontally between one end and the other end of the upper portion of the entrance and be connected to one driving motor and the control piece.

The tower-type blower fan 220-2 may be provided as a straight-line tower fan at the upper portion of the entrance so that the blowing amount and the gas speed for the entire upper portion of the entrance are uniformly controlled by the one driving motor and the control piece.

Particularly, the tower-type blower fan 220-2 may be installed at one side of the outside of the body part 210 to communicate with a communication tube 220-3 therein at the upper portion of the body part 210 so that the blowing amount and the gas speed for the entire upper portion of the entrance from the outside of the body part 210 are uniformly controlled by the one driving motor and the control piece.

The dispersion part 230 may be a dispersion unit installed at the lower portion of the body part 210 to evenly disperse the gas supplied into the body part 210 downward in a straight line to discharge the gas so as to form a gas layer and may be provided with a distribution tube having a plurality of distribution holes defined in a honeycomb shape in cross-section to evenly distribute the gas in the straight line to the upper portion of the entrance.

In addition, as illustrated in FIGS. 14 and 15, the device for controlling the gas flow of the EFEM according to the present invention may further include a nozzle part 240 installed at a lower portion of the front surface of the entrance to supply the gas such as the purge gas or the pure air upward or inward.

The nozzle part 240 may be a supply unit installed at the lower portion of the front surface of the entrance to supply the gas such as the purge gas or the pure air upward or inward and may be provided as a gas nozzle installed at each of both ends of the lower portion of the entrance to inject the gas such as the purge gas or the pure air into the wafer container and be installed to be changed in injection angle in a forward and backward direction and a left and right direction.

The gas nozzle may include a first nozzle 241 installed at one end of the lower portion of the entrance to inject the gas such as the purge gas or the pure air into the central portion of the inside of the wafer container, and a second nozzle 242 installed at the other end of the lower portion of the entrance to inject the gas such as the purge gas or the pure air into the central portion of the inside of the wafer container.

In addition, as illustrated in FIGS. 16 and 17, the device for controlling the gas flow of the EFEM according to the present invention may further include a gas injection part 250 installed at an upper portion or a side portion of the body part 210 to inject a nitrogen gas or a low-humidity gas into the upper portion of the entrance.

The gas injection part 250 may be an injection unit installed at the upper or side portion of the body part 210 to inject the nitrogen gas or the low-humidity gas into the upper portion of the entrance. As illustrated in FIG. 16, the gas injection part 250 may be installed at the upper portion of the body part 210 and also installed at the upper portion of the blower part 220 to inject the nitrogen gas or the low-humidity gas by the blower part 220 and the dispersion part 230 so as to form the gas layer at the entrance and change the injection angle in the forward and backward direction and the left and right direction.

In addition, as illustrated in FIG. 17, the gas injection part 250 may be installed at a lower end of the side portion of the body part 210 to directly inject the nitrogen gas or the low-humidity gas to the upper portion of the entrance, thereby forming the gas layer at the entrance. Here, a double gas layer may be formed together with the gas layer formed at the entrance by the blower part 220 and the dispersion part 230 and be changed in injection angle in the forward and backward direction and the left and right direction.

In addition, as illustrated in FIGS. 8 and 9, the device for controlling the gas flow of the EFEM according to the present invention may further include a filter part 260 installed between the blower part 220 and the dispersion part 230 to filter the gas supplied by the blower part 220.

The filter part 260 may be a filtering unit installed between the blower part 220 and the dispersion part 230 to filter the gas supplied by the blower part 220 and may be provided as a filter member such as an ULPA filter or a HEPA filter that filters and removes impurities such as foreign substances or fine dust contained in the gas.

In addition, an opening and closing piece installed at one side of the main body 211 of the body part 210 so that a portion of the main body 211 is opened and closed when replacing the filter member of the filter part 260 installed in the internal space of the main body 211.

In addition, as illustrated in FIGS. 8 and 9, the device for controlling the gas flow of the EFEM according to the present invention may further include a control part 270 connected to the blower part 220 to control an air amount of the blower part 220.

The control part 270 may be a control unit installed at one side of the outside of the body part 210 and connected to the blower part 220 to control the air amount of the blower part 220 and may be provided with a controller 271, a connection terminal 272, and a connection cable 273.

The controller 271 may be a control unit installed at one side of the outside of the body part 210 or installed inside a body 211 installed outside the main body 211 of the body part 210 and may be provided as a controller that compares a measured value of the internal humidity of the wafer container 120 with a set value by a measuring unit such as a humidity sensor to control the blowing amount of each blower fan of the blower part 220.

The connection terminal 272 may be a connection unit installed inside the body installed outside the main body 211 of the body part 210 and may be provided as a terminal such as a terminal connected to each blower fan of the blower part 220 by interposing a cable to control the blowing amount of each blower fan of the blower part 220.

The connecting cable 273 may be a connection unit connected between the controller 271 and the connection terminal 272 and may be configured to transmit a control signal from the controller 271 to the connection terminal 272 by interposing the connection cable 273, thereby controlling the gas flow for each blower fan of the blower unit 220.

Hereinafter, the device for controlling the gas flow of the EFEM according to a preferred embodiment of the present invention will be described in more detail with reference to the attached drawings.

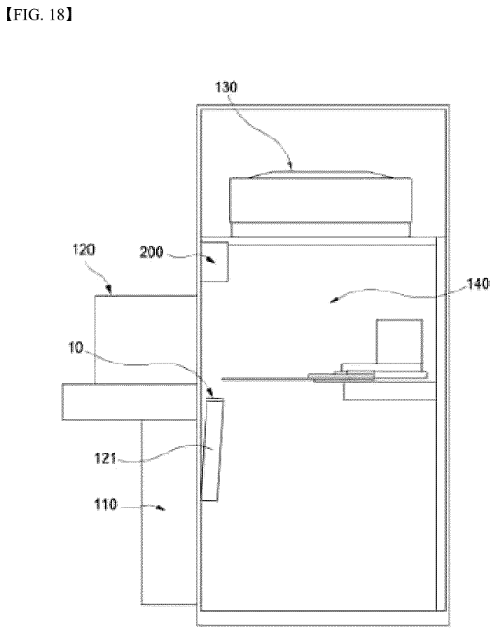

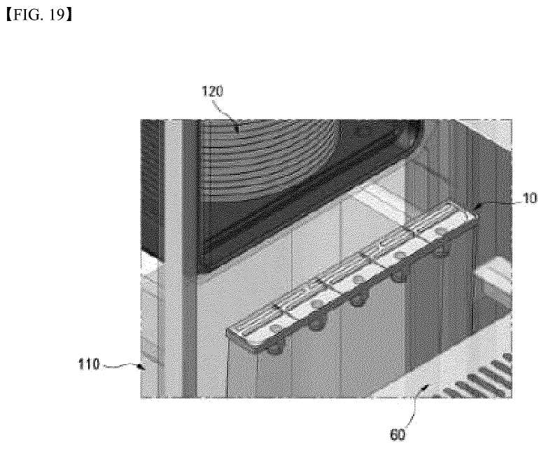

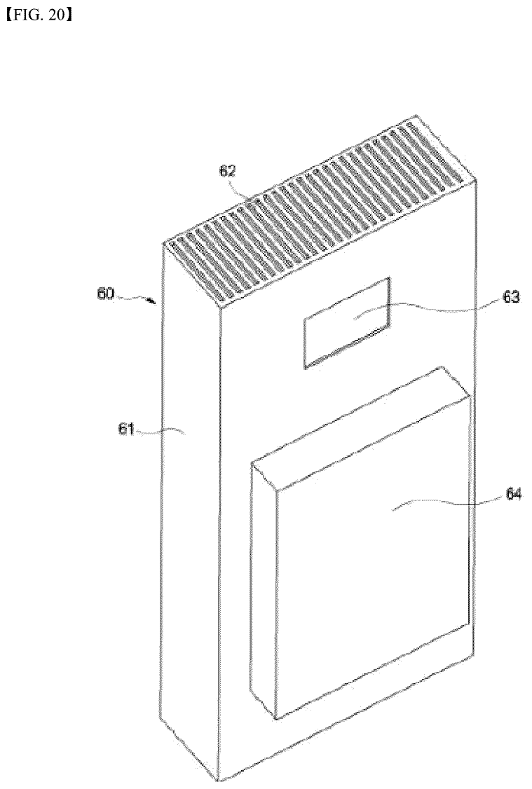

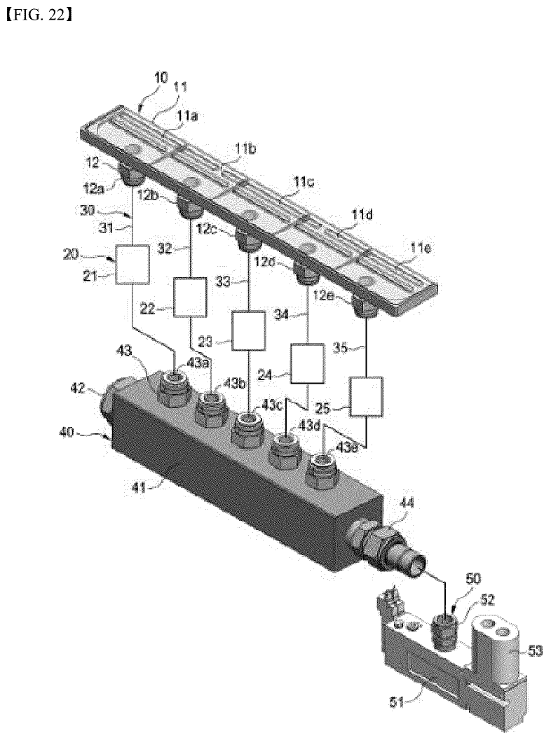

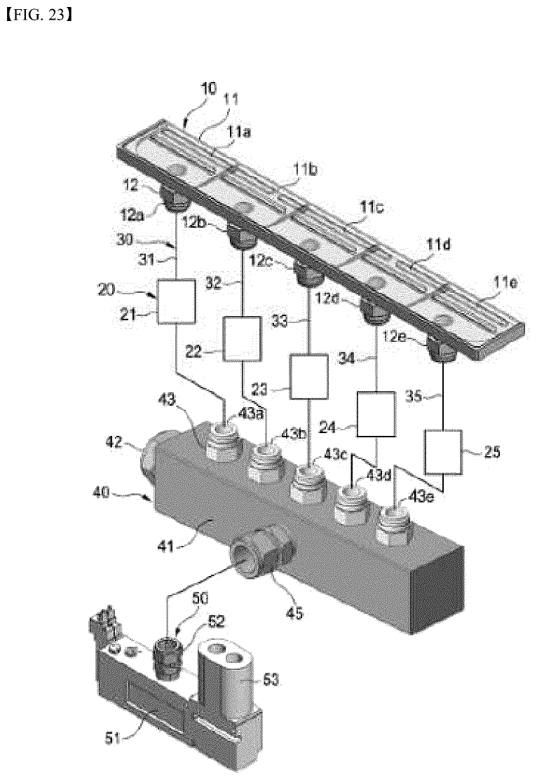

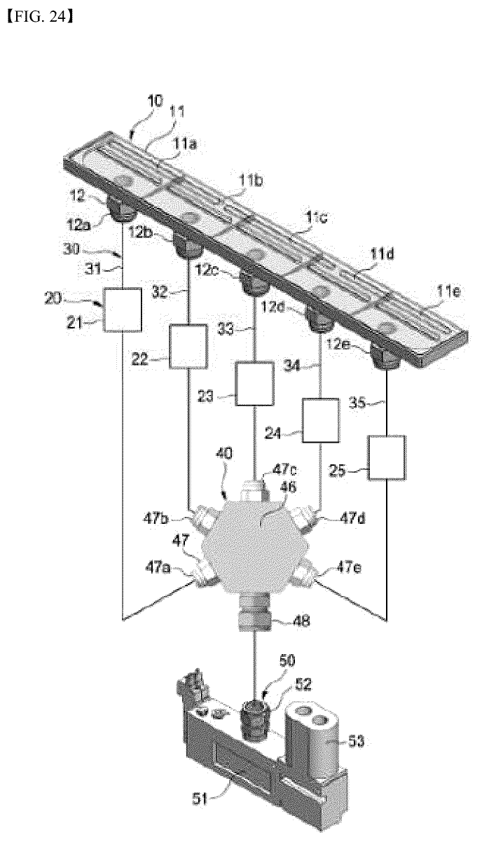

FIG. 18 is a view illustrating an example of a semiconductor process apparatus provided with the device for controlling the gas flow of the EFEM according to an embodiment of the present invention, FIG. 19 is a view illustrating a state in which the device for controlling the gas flow of the EFEM is installed according to an embodiment of the present invention, FIG. 20 is a view illustrating a cover part of the device for controlling the gas flow of the EFEM according to an embodiment of the present invention, FIG. 21 is a view illustrating another example of the semiconductor process apparatus provided with the device for controlling the gas flow of the EFEM according to an embodiment of the present invention, FIG. 22 is a view illustrating an example of the device for controlling the gas flow of the EFEM according to an embodiment of the present invention, FIG. 23 is a view illustrating another example of the device for controlling the gas flow of the EFEM according to an embodiment of the present invention, and FIG. 24 is a view illustrating further another example of the device for controlling the gas flow of the EFEM according to an embodiment of the present invention.

A semiconductor process apparatus of the present invention may be a semiconductor process apparatus provided with the device for controlling the gas flow of the EFEM according to this embodiment, and as illustrated in FIG. 18 and FIG. 21, may include a load port module (LPM) 110, a wafer container 120 (e.g., front opening unified pod (FOUP)), a fan filter unit (FFU) 130, and a wafer transfer chamber 140 and may be provided as an equipment front end module (EFEM) on which a device for controlling a gas flow of the EFEM is mounted.

The load port module (LPM) 110 may be a device that opens or closes a door 121 of the wafer container 120 (e.g., front opening universal pod (FOUP)) containing wafers for semiconductor manufacturing to transfer the wafers.

This load port module (LPM) 110 may be configured to inject a nitrogen gas into the wafer container 120 (e.g., front opening unified pod (FOUP)) when the wafer container 120 is mounted on a stage unit and discharge contaminants inside the wafer container 120 to the outside of the wafer container 120, thereby preventing the wafers stored and transferred in the wafer container 120 from being damaged by the contaminants.

The wafer container 120 may have a loading space, in which the plurality of wafers are loaded, therein, and the door may be opened to load or unload the wafers. The wafer container 120 may be provided as the front-opening unified pods (FOUP).

The fan filter unit 130 may be installed at an upper portion of the wafer transfer chamber 140 to remove molecular contaminants such as fumes and fine particles such as dusts, thereby maintaining air inside the wafer transfer chamber 140 in a clean state. Typically, an air flow within the wafer transfer chamber 140 may be formed downward from the upper portion, at which the fan filter unit 130 is installed.

The wafer transfer chamber 140 may be a space member defined between the wafer container 120, in which the plurality of wafers are loaded, and a processing space 160, in which the wafers are processed in the semiconductor process, and provided with a door unit 161.

The wafer transfer chamber 140 may be provided with an exhaust device at a lower portion thereof to maintain a clean space so as to minimize the foreign substances or the contaminants from being attached to the wafer while the wafer is transferred from one processing space to another processing space by the transfer unit 150 such as the transfer robot.

As illustrated in FIGS. 18 to 20, the device for controlling the gas flow of the EFEM according to this embodiment may include an intake part 10, a control part 20, a tube part 30, a manifold part 40, an exhaust part 50, and a cover part 60 and may be provided as a device for controlling the gas flow of the EFEM that is installed at one or both sides of the internal space of the EFEM and is installed at the entrance, through which the wafers are loaded and unloaded, to suction and discharge a large amount of fumes generated after the semiconductor process to stabilize the gas flow.

The intake part 10 may be an intake member in which an intake space is divided into a plurality of intake zones in a wafer access door of the wafer container 120 or the processing space 160 of the EFEM and may be provided with a plurality of intake zones 11 and an intake port 12.

The intake zone 11 may be an intake unit provided in plurality for each zone in the intake space and may be provided with a first intake zone 11a, a second intake zone 11b, a third intake zone 11c, a fourth intake zone 11d, and a fifth intake zone 11e to divide the intake space into five intake zones.

The intake port 12 may be an intake unit provided downstream of the intake zone 11 and may be provided with a first intake port 12a, a second intake port 12b, a third intake port 12c, a fourth intake port 12d, and a fifth intake port 12e, which are provided corresponding to the five intake zones.

The control part 20 may be a control member installed in a communication path of the tube part 30 to individually control an intake amount of each of the plurality of intake zones 11 and the intake ports 12 and may be provided with a first control valve 21, a second control valve 22, a third control valve 23, a fourth control valve 24, and a fifth control valve 25 to control the intake amount corresponding to the five intake zones 11 and intake ports 12.

The tube part 30 may be a tube member that is connected to the intake part 10 to communicate with each intake zone and may be provided with a first tube 31, a second tube 32, a third tube 33, a fourth tube 34, and a fifth tube 35 so as to be connected corresponding to the five intake zones 11 and intake ports 12.

An example of the manifold part 40 may be a combination member that is connected downstream of the tube part 30 to combine the intake gas of the respective intake parts, and as illustrated in FIGS. 22 and 23, an example of the manifold part 40 may be provided with a first manifold 41, a first exhaust port 42, a first inlet 43, and a first outlet.

The first manifold 41 may be a joining member that joins the intake air suctioned from each intake zone 11 of the intake part 10 and may be provided in a rectangular cylinder shape so that the intake air is introduced from an upper side and discharged to one end of a side or a central portion of a side surface.

The first exhaust port 42 may be an exhaust member installed at one side of the first manifold 41 to discharge a residual gas and may be installed at the other side of the side surface of the first manifold 41 to discharge the residual intake gas inside the first manifold 41.

The first inlet 43 may be an inlet member that is installed at an upper portion of the first manifold 41 and is connected to each of the intake zones 11 of the intake part 10 to introduce the intake air and may be provided with a first-1 inlet 43a, a first-2 inlet 43b, a first-3 inlet 43c, a first-4 inlet 43d, and a first-5 inlet 43e so as to be connected correspondingly to the five intake zones 11 and intake ports 12.

The first outlet may be an outlet member that is installed on the other side of the first manifold 41 to discharge the intake air and may be provided with an eleventh outlet 44 installed at the other side of the first manifold 41 to correspond to the first exhaust port 42 as illustrated in FIG. 22 or a twelfth outlet 45 installed at the other side of the first manifold 41 and installed at a central portion of each of the plurality of first inlets 43 as illustrated in FIG. 23.

Another example of the manifold part 40 may be a combination member that is connected downstream of a tube part 30 to combine the intake gas of each intake zone. As illustrated in FIG. 24, another example of the manifold part 40 may be provided with a second manifold 46, a second inlet 47, and a second outlet 48.

The second manifold 46 may be a joining member that joins the intake air suctioned from each intake zone of the intake part 10 and may be provided in a hexagonal cylinder shape so that the intake air is introduced from an upper portion and a side portion of the hexagon and discharged to a central portion of a lower portion of the hexagon.

The second inlet 47 may be an inlet member that is installed at a circumference of the second manifold 46 and is connected to each of the intake zones 11 of the intake part 10 to introduce the intake air and may be provided with a second-1 inlet 47a, a second-2 inlet 47b, a second-3 inlet 47c, a second-4 inlet 47d, and a second-5 inlet 47e so as to be connected correspondingly to the five intake zones 11 and intake ports 12.

The second outlet 48 may be a discharge member installed at a lower portion of the second manifold 46 to discharge the intake air to the outside and may be configured to discharge the intake air downward at the lower portion of the second manifold 46.

The discharge part 50 may be a discharge member installed at one side of the manifold part 40 to provide suction force to the manifold part 40 to discharge suction air that has introduced into the manifold part 40 and may be provided with a suction unit 51, an input port 52, and an discharge port 53.

The suction unit 51 may be a driving unit installed downstream of the manifold part 40 to provide suction force to the suction part 10 and may be provided with a driving unit such as an ejector, a fan, a pump, an exhaust facility, or a negative pressure facility that forms a negative pressure to provide the suction force to the suction part 10.

The input port 52 may be an input member installed upstream of the suction unit 51 to inject air by the suction force of the suction unit 51 and may be configured to form an intake passage to inject air from the intake part 10 and the manifold part 40.

The discharge port 53 may be a discharge member installed downstream of the suction unit 51 to discharge the intake air to the outside and may be configured to form an exhaust passage to discharge the intake air supplied from the intake part 10 and the manifold part 40.

The cover part 60 may be a cover member that is installed outside the intake part 10, the tube part 30, the control part 20, the manifold part 40, and the discharge part 50 to cover the above-described components and may be provided with a main cover 61, a cover intake port 62, a viewing hole 63, and a sub-cover 64 as illustrated in FIG. 20.

The main cover 61 may be provided in a square box shape to cover the entire area, and the cover intake port 62 may be provided as an intake port with a plurality of slots punched in an upper portion of the main cover 61.

The viewing hole 63 may be provided as a punched window at an upper portion of side surface of the main cover, and the sub-cover 64 may be provided to protrude outward at a central portion of the side surface of the main cover 61 to cover control equipment such as an utility.

As described above, according to the present invention, the body part, the blower part, and the dispersion part may be installed at one side or both sides in the internal space of the EFEM to form the gas layer at the entrance of the water, thereby forming the gas layer at the entrance of the wafer and forming the blocking gas layer at the entrance so as to reduce the humidity of the wafer container.

In addition, the nozzle part installed at the lower portion of the front surface of the entrance of the wafer to supply the gas upward or inward may be further provided to form the multiple gas layers by the downward flow in the blower part and upward flow or inward flow in the nozzle part, thereby reducing the interference due to the flow of the air in the wafer transfer chamber and reducing the flow of the gas that forms the external air blocking gas layer.

In addition, the gas injection part that injects the nitrogen gas or the low-humidity gas into the upper portion of the entrance from the upper or side portion of the body part may be further provided to solve the limitations of increasing in time required for unloading and loading the wafer due to the conventional complex load port and improve the manufacturing yield of the semiconductor while effectively blocking the external air.

In addition, the plurality of blower fans may be provided as the blower part, and the blowing amount of each of the blower fans may be individually controlled by the control part to finely control the blowing amount for each areas, thereby improving the maintenance performance of the gas layer and uniformly maintaining the gas layer for each areas.

In addition, the distribution tube having the plurality of through-holes with the cross-section in the honeycomb shape may be provided as the distribution part to evenly distribute the gas in the straight line to the upper portion of the entrance, thereby uniformly maintaining the gas layer.

In addition, the filter part may be further provided between the blower part and the dispersion part to filter the gas supplied by the blower part so as to remove the foreign substances or the impurities such as the fine dusts contained in the gas through the filtration, thereby preventing the contamination of the gas distributed and supplied by the blower part and the dispersion part so as to improve the yield of the wafer container.

In addition, the large amount of fumes may be suctioned and discharged after the semiconductor process to decrease in humidity inside the FOUP, thereby improving the semiconductor production yield.

In addition, the device for controlling the gas flow of the EFEM may be installed in the door of the FOUP of the EFEM of the semiconductor equipment to suction and discharge the corrosive gas and the external air inside the FOUP.

In addition, the plurality of intake ports and intake zones may be partitioned in the upper portion of the door, and the plurality of suction zones may be divided into the plurality of parts to control the intake amount for each positions, thereby improving the suction uniformity for the suction efficiency of the corrosive gas and the external air.

In addition, the intake part, the tube part, the control part, the manifold part, and the discharge part may be sequentially disposed downward to improve the intake performance and the discharge performance and also improve the stabilization of the gas flow.

As described above, the present invention may provide the effect of blocking the introduction of the external air by installing the body part, the blower part, and the dispersion part at one side or both sides in the internal space of the EFEM to form the gas layer at the entrance of the wafer, thereby forming the blocking gas layer at the entrance so as to reduce the humidity of the wafer container.

In addition, the nozzle part installed at the lower portion of the front surface of the entrance of the wafer to supply the gas upward or inward may be further provided to form the multiple gas layers by the downward flow in the blower part and upward flow or inward flow in the nozzle part, thereby reducing the interference due to the flow of the air in the wafer transfer chamber and reducing the flow of the gas that forms the external air blocking gas layer.

In addition, the gas injection part that injects the gas into the upper portion of the entrance from the upper or side portion of the body part may be further provided to solve the limitations of increasing in time required for unloading and loading the wafer due to the conventional complex load port and improve the manufacturing yield of the semiconductor while effectively blocking the external air.

In addition, the plurality of blower fans may be provided as the blower part, and the blowing amount of each of the blower fans may be individually controlled by the control part to finely control the blowing amount for each areas, thereby improving the maintenance performance of the gas layer and uniformly maintaining the gas layer for each areas.

In addition, the distribution tube having the plurality of through-holes with the cross-section in the honeycomb shape may be provided as the distribution part to evenly distribute the gas in the straight line to the upper portion of the entrance, thereby uniformly maintaining the gas layer.

In addition, the filter part may be further provided between the blower part and the dispersion part to filter the gas supplied by the blower part so as to remove the foreign substances or the impurities such as the fine dusts contained in the gas through the filtration, thereby preventing the contamination of the gas distributed and supplied by the blower part and the dispersion part so as to improve the yield of the wafer container.

In addition, the large amount of fumes may be suctioned and discharged after the semiconductor process to decrease in humidity inside the FOUP, thereby improving the semiconductor production yield.

In addition, the device for controlling the gas flow of the EFEM may be installed in the door of the FOUP of the EFEM of the semiconductor equipment to suction and discharge the corrosive gas and the external air inside the FOUP.

In addition, the plurality of intake ports and intake zones may be partitioned in the upper portion of the door, and the plurality of suction zones may be divided into the plurality of parts to control the intake amount for each positions, thereby improving the suction uniformity for the suction efficiency of the corrosive gas and the external air.

In addition, the intake part, the tube part, the control part, the manifold part, and the discharge part may be sequentially disposed downward to improve the intake performance and the discharge performance and also improve the stabilization of the gas flow.

The foregoing present invention may be carried out in various embodiments without departing from the technical ideas or primary features. Therefore, the above-described embodiments are merely illustrative of the present invention, but should not be limitedly interpreted.

What is claimed is:

1. A device for controlling a gas flow of an equipment front end module (EFEM), which is installed at one side or each of both sides of an internal space of the EFEM, wherein the device is installed at an entrance, through which a wafer is loaded and unloaded, to supply a gas to stabilize the gas flow, the device comprising:
a body part (210) installed at an upper portion of a front surface of the entrance;
a blower part (220) configured to blow the gas so that the gas is supplied into the body part (210); and
a dispersion part (230) installed at a lower portion of the body part (210), wherein the gas supplied into the body part (210) is uniformly dispersed downward in a straight line to discharge the gas, thereby forming a gas layer.

2. The device of claim 1, further comprising a nozzle part (240) installed at a lower portion of the front surface of the entrance to supply the gas upward or inward.

3. The device of claim 2, wherein the nozzle part (240) is provided as a gas nozzle installed at each of both ends of the lower portion of the entrance to inject the gas into a wafer container.

4. The device of claim 1, further comprising a gas injection part (250) installed at an upper portion or a side portion of the body part (210) to inject a nitrogen gas or a low-humidity gas to the upper portion of the entrance.

5. The device of claim 1, wherein the body part (210) comprises:
a cylindrical main body which is provided to be penetrated in a vertical direction and in which partition walls are installed to partition an internal space into a plurality of spaces, respectively;
an inclined piece installed to be inclined at an upper portion of the main body; and
a cover piece which is installed to be coupled to an upper portion of the inclined piece and in which a plurality of through-holes are punched.

6. The device of claim 1, wherein the blower part (220) is provided as a blower unit installed inside the body part (210) or installed to be connected outside the body part (210) by interposing a connection tube therein.

7. The device of claim 6, wherein the blower unit comprises:
one or more first blower fans installed at one side portion of the body part (210);
one or more second blower fans installed at a central portion of the body part (210); and
one or more third blower fans installed at the other side potion of the body part (210).

8. The device of claim 6, wherein the blower part (220) is provided with partition walls configured to partition a blowing space of the blower unit into a plurality of spaces.

9. The device of claim 1, wherein the dispersion part (230) is provided as a distribution tube in which a plurality of through-holes having a cross-section in a honeycomb shape so that the gas is distributed and injected to the upper portion of the entrance in a straight line.

10. The device of claim 1, further comprising a filter part (260) installed between the blower part (220) and the dispersion part (230) to filter the gas supplied by the blower part (220).

11. The device of claim 1, further comprising a control part (270) connected to the blower part (220) to control a blowing amount of the blower part (220).

12. A semiconductor process apparatus provided with the device for controlling the gas flow of the EFEM as set forth in claim 1.

13. A device for controlling a gas flow of an equipment front end module (EFEM), which is installed at one side or each of both sides of an internal space of the EFEM, wherein the device is installed at an entrance, through which a wafer is loaded and unloaded, to intake a gas to stabilize the gas flow, the device comprising:
an intake part (10) in which an intake space is partitioned into a plurality of intake zones at a wafer entrance door;
a tube part (30) connected to the intake part (10) to communicate with each of the intake zones;
a control part (20) installed in a communication path of the of the tube part (30) to individually control an intake amount of each of the intake zones;
a manifold part (40) connected downstream of the tube part (30) to combine an intake gas of each of the intake zones; and
a discharge part (50) installed at one side of the manifold part (40) to provide intake force to the manifold part (40), thereby discharging the intake gas introduced into the manifold part (40).

14. The device of claim 13, wherein the intake part (10) comprises:
an intake zone that is partitioned into a plurality of zones so that the gas is suctioned for each zone in the intake space; and
an intake port provided downstream of each of the intake zones.

15. The device of claim 13, wherein the manifold part (40) comprises:
a first manifold configured to combine the intake gas suctioned from each of the intake zones of the intake part (10);
a first exhaust port installed at one side of the first manifold to discharge a residual gas;
a first inlet installed at an upper portion of the first manifold and connected to each intake zone of the intake part (10) to introduce the intake gas; and
a first outlet installed at the other side of the first manifold to discharge the intake gas.

16. The device of claim 13, wherein the manifold part (40) comprises:
a second manifold configured to combine the intake gas suctioned from each of the intake zones of the intake part (10);
a second inlet installed at a circumference of the second manifold and connected to each intake zone of the intake part (10) to introduce the intake gas; and
a second outlet installed at a lower portion of the second manifold to discharge the intake gas.

17. The device of claim 13, wherein the discharge part (50) comprises:
a suction unit installed downstream of the manifold part (40) to provide intake force;
an input port installed upstream of the suction unit to input the intake gas; and
a discharge port installed downstream of the suction unit to discharge the intake gas.

18. A semiconductor process apparatus provided with the device for controlling the gas flow of the EFEM as set forth in claim 13.
